(19) United States
(12) Patent Application Publication
(10) Pub. No.: US 2007/0056846 A1
(43) Pub. Date: Mar. 15, 2007

(54) Silicon dot forming method and silicon dot forming apparatus

(75) Inventors: Eiji Takahashi, Kyoto-shi (JP); Atsushi Tomyo, Kyoto-shi (JP); Kenji Kato, Kyoto-shi (JP); Takashi Mikami, Kyoto-shi (JP); Tsukasa Hayashi, Kyoto-shi (JP)

Correspondence Address: RADER FISHMAN & GRAUER PLLC, LION BUILDING, 1233 20TH STREET N.W., SUITE 501, WASHINGTON, DC, 20036, US

(73) Assignee: NISSIN ELECTRIC CO., LTD.

(21) Appl. No.: 11/519,967

(22) Filed: Sep. 13, 2006

(30) Foreign Application Priority Data
Sep. 13, 2005 (JP) 2005-264939

(51) Int. Cl. C23C 14/00

(52) U.S. Cl. 204/192.25; 204/298.13

(57) ABSTRACT

A substrate is accommodated in a vacuum chamber provided with a silicon sputter target, a sputtering gas (typically a hydrogen gas) is supplied into the vacuum chamber, a high-frequency power is applied to the gas to form plasma in the chamber, a bias voltage is applied to the target for control of chemical sputtering, and the chemical sputtering is effected on the target by the plasma to form silicon dots on the substrate.

### CROSS-REFERENCE TO RELATED APPLICATION

This invention is based on Japanese Patent Applicaion No. 2005-264939 filed in Japan on Sep. 13, 2005, the entire content of which is hereby incorporated by reference.

### BACKGROUND OF THE INVENTION

1. Field of the Invention

The present invention relates to a method and an apparatus for forming silicon dots (i.e., so-called silicon nanoparticles) of minute sizes on a substrate that can be used as electronic device materials for single-electron devices and the like, and light emission materials and others.

2. Description of the Related Art

Silicon dots can be used for forming electronic devices (e.g., memory elements using charge storing capability of silicon dots), light emission elements, etc.

As a method of forming silicon dots, such a physical manner has been known that silicon is heated and vaporized in an inert gas by excimer laser or the like to form silicon dots on a substrate. Also, an in-gas vaporizing method is known (see Kanagawa-ken Sangyo Gijutu Sougou Kenkyusho Research Report No. 9/2003, pp 77-78). The latter method is configured to heat and vaporize the silicon to form silicon dots on a substrate by high-frequency induction heating or arc discharge instead of laser.

Such a CVD method is further known that a material gas is supplied into a CVD chamber, and silicon nanoparticles are formed on a heated substrate [see Japanese Laid-Open Patent Publication No. 2004-179658 (JP2004-179658A)].

In this method, nucleuses for growing silicon nanoparticles are formed on the substrate, and then the silicon nanoparticles are grown from the nucleuses.

However, the method of heating and vaporizing the silicon by laser irradiation can not uniformly control an energy density for irradiating the silicon with the laser, and therefore it is difficult to uniformize the particle diameters and density distribution of silicon dots.

In the in-gas vaporizing method, the silicon is heated nonuniformly, and therefore the particle diameters and the density distribution of silicon dots can not be uniformized without difficulty.

In the foregoing CVD method, the substrate must be heated to 550 deg. C. or higher for forming the nucleuses on the substrate, and the substrate of a low heat resistance can not be employed, which narrows a selection range of the substrate material.

### SUMMARY OF THE INVENTION

Accordingly, a first object of the invention is to provide a silicon dot forming method in which silicon dots having substantially uniform particle diameters and exhibiting a substantially uniform density distribution are formed directly on a silicon dot formation target substrate at a lower temperature.

Also, it is a second object of the invention to provide a silicon dot forming apparatus, wherein silicon dots having substantially uniform particle diameters and exhibiting a substantially uniform density distribution can be formed on a silicon dot formation target substrate at a lower temperature.

The inventors made a research for achieving the above objects, and found the followings.

Plasma is formed from a sputtering gas (i.e., gas for sputtering such as a hydrogen gas), and chemical sputtering (reactive sputtering) is effected on a silicon sputter target with the plasma thus formed so that crystalline silicon dots having substantially uniform particle diameters and exhibiting a substantially uniform density distribution can be formed directly on the silicon dot formation target substrate at a low temperature.

Also, when chemical sputtering (reactive sputtering) is effected on a silicon sputter target with the plasma thus formed, a bias voltage for controlling sputtering (voltage for controlling the amount of sputtering) is applied to the silicon sputter target, whereby incident energy of charged particles from the plasma to silicon sputter target is controlled to control the sputter amount. Thereby silicon dots of the desired particle diameter can be formed.

Such a plasma may be employed that a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission is 10.0 or lower, preferably 3.0 or lower, or 0.5 or lower.

Chemical sputtering with this plasma can form the crystalline silicon dots having substantially uniform particle diameters in a range not exceeding 20 nm(nanometers) (and further 10 nm) and exhibiting a substantially uniform density distribution on the substrate even at a low temperature of 500 deg. C. or lower.

The plasma can be formed by supplying the sputtering gas (e.g., hydrogen gas) to a plasma formation region, and applying a high-frequency power thereto.

In any one of the above cases, the “substantially uniform particle diameters” of the silicon dots according to the invention represents the case where all the silicon dots have the equal or substantially equal particle diameters as well as the case where the silicon dots have particle diameters which are not uniform to a certain extent, but can be practically deemed as the substantially uniform particle diameters.

For example, it may be deemed without any practical problem that the silicon dots have substantially uniform particle diameters when the particle diameters of the silicon dots fall or substantially fall within a predetermined range (e.g., not exceeding 20 nm, or not exceeding 10 nm).

Also, even in the case where the particle diameters of the silicon dots are spread over a range from 5 nm to 6 nm and a range from 8 nm to 11 nm, it may be deemed without any practical problem that the particle diameters of the silicon dots substantially fall within a predetermined range (e.g., not exceeding 10 nm) as a whole.

In these cases, the silicon dots have the “substantially uniform particle diameters” according to the invention. In summary, the “substantially uniform particle diameters” of the silicon dots represents the particle diameters which are substantially uniform as a whole from a practical viewpoint.

Based on the above findings, the invention provides the following silicon dot forming method to achieve the first object: the method including a step of arranging a silicon dot formation target substrate in a silicon dot forming vacuum chamber having at least one silicon sputter target, and a silicon dot forming step of forming silicon dots on the silicon dot formation target substrate, wherein a sputtering gas is supplied into the vacuum chamber, a high-frequency power is applied to the gas to generate plasma in the vacuum chamber and a bias voltage for controlling chemical sputtering is applied to the silicon sputter target, and chemical sputtering is effected on the silicon sputter target by the plasma to form silicon dots on the silicon dot formation target substrate.

The invention provides a first to third silicon dot forming apparatuses as described below to achieve the second object.

(1) First Silicon Dot Forming Apparatus

A silicon dot forming apparatus including:
a silicon dot forming vacuum chamber having a holder for holding a silicon dot formation target substrate;
a silicon sputter target arranged in the vacuum chamber;
a hydrogen gas supply device supplying a hydrogen gas into the vacuum chamber;
an exhaust device exhausting a gas from the vacuum chamber;
a high-frequency power applying device applying a high-frequency power to the hydrogen gas supplied into the vacuum chamber from the hydrogen gas supply device, and thereby forming plasma for chemical sputtering on the silicon sputter target; and
a bias applying device applying a bias voltage to the silicon sputter target in effecting the chemical sputtering on the silicon sputter target by the plasma for control of the chemical sputtering.
   (2) Second Silicon Dot Forming Apparatus
A silicon dot forming apparatus including:
a silicon dot forming vacuum chamber having a holder for holding a silicon dot formation target substrate;
a hydrogen gas supply device supplying a hydrogen gas into the vacuum chamber;
a silane-containing gas supply device supplying a silane-containing gas into the vacuum chamber;
an exhaust device exhausting a gas from the vacuum chamber;
a first high-frequency power applying device applying a high-frequency power to the hydrogen gas supplied into the vacuum chamber from the hydrogen gas supply device and the silane-containing gas supplied into the vacuum chamber from the silane-containing gas supply device, and thereby forming plasma for forming a silicon film on an inner wall of the vacuum chamber;
a second high-frequency power applying device applying a high-frequency power to the hydrogen gas supplied from the hydrogen gas supply device into the vacuum chamber after formation of the silicon film, and thereby forming plasma for effecting chemical sputtering on the silicon film serving as a silicon sputter target; and
a bias applying device applying a bias voltage to the silicon sputter target in effecting chemical sputtering on the silicon sputter target by the plasma produced from the hydrogen gas for control of the chemical sputtering.
   (3) Third Silicon Dot Forming Apparatus
A silicon dot forming apparatus including:
a first vacuum chamber having a holder for holding a target substrate;
a first hydrogen gas supply device supplying a hydrogen gas into the first vacuum chamber;
a silane-containing gas supply device supplying a silane-containing gas into the first vacuum chamber;
a first exhaust device exhausting a gas from the first vacuum chamber;
a first high-frequency power applying device applying a high-frequency power to the hydrogen gas supplied into the first vacuum chamber from the first hydrogen gas supply device and the silane-containing gas supplied into the first vacuum chamber from the silane-containing gas supply device, and thereby forming plasma for forming a silicon film on the target substrate to obtain a silicon sputter target;
a second vacuum chamber for forming silicon dots communicated with the first vacuum chamber in an airtight fashion with respect to an ambient air and having a holder for holding a silicon dot formation target substrate;
a transferring device transferring the silicon sputter target from the first vacuum chamber into the second vacuum chamber without exposing the silicon sputter target to the ambient air;
a second hydrogen gas supply device supplying a hydrogen gas into the second vacuum chamber;
a second exhaust device exhausting a gas from the second vacuum chamber;
a second high-frequency power applying device applying a high-frequency power to the hydrogen gas supplied from the second hydrogen gas supply device into the second vacuum chamber, and thereby forming plasma for effecting chemical sputtering on the silicon sputter target transferred into the second vacuum chamber; and
a bias applying device applying a bias voltage to the silicon sputter target for control of the chemical sputtering in effecting chemical sputtering on the silicon sputter target by the plasma for chemical sputtering.

The foregoing and other objects, features, aspects and advantages of the present invention will become more apparent from the following detailed description when taken in conjunction with accompanying drawings.

### BRIEF DESCRIPTION OF THE DRAWINGS

FIG. 1 shows an example of a silicon dot forming apparatus according to the invention.

FIG. 2 is a block diagram illustrating an example of an optical emission spectroscopic analyzer for plasma.

FIG. 3 is a block diagram illustrating an example of a circuit performing control of an exhaust amount (vacuum chamber internal pressure) by an exhaust device and the like.

FIG. 4 shows another example of an silicon dot forming apparatus.

FIG. 5 illustrates a positional relationship between a target substrate for forming a silicon film, electrodes and the like.

FIG. 6 shows another example of the silicon dot forming apparatus.

FIG. 7 is a perspective view of a high-frequency anttena for forming an inductively coupled plasma in the apparatus of FIG. 6.

FIG. 8 shows another example of the silicon dot forming apparatus.

FIG. 9 is a section view schematically showing an example of the substrate having silicon dots.

### DESCRIPTION OF THE PREFERRED EMBODIMENTS

A silicon dot forming method according to preferred embodiment of the invention includes fundamentally a step of arranging a silicon dot formation target substrate in a silicon dot forming vacuum chamber provided with at least one silicon sputter target therein, and a silicon dot forming step of forming silicon dots on the silicon dot formation target substrate.

In the silicon dot forming step, a sputtering gas is supplied into the vacuum chamber, and a high-frequency power is applied to the gas to form plasma in the vacuum chamber and a bias voltage is applied to the silicon sputter target for control of chemical sputtering on the target. Then, the chemical sputtering is effected by the plasma on the silicon sputter target to form silicon dots on the silicon dot formation target substrate.

The term “silicon dot” refers to so-called “silicon nanoparticle” that is a silicon dot of minute size of 100 nm(nanometers) or less in particle diameter e.g., size of a few nanometers to dozens of nanometers. As to lower limit of the size of the silicon dot, it is not restrictive. In view of difficulty of formation, the size is substantially 1 nm.

According to such silicon dot forming method, crystalline silicon dots having substantially uniform particle diameters and exhibiting a substantially uniform density distribution can be formed directly on the silicon dot formation target substrate at a low temperature (e.g., at 500 deg. C. or lower).

Silicon sputter targets can be obtained in the market and may be used at a prepared form in an independent step. However, at least one of silicon sputter target(s) may be a silicon film formed on the inner wall of the vacuum chamber. The silicon film may be formed as follows.

A silane-containing gas and a hydrogen gas are supplied into the vacuum chamber before placing the silicon dot formation target substrate into the chamber and a high-frequency power is applied to the gases to form plasma in the vacuum chamber for formation of the silicon film on the inner wall of the vacuum chamber with the plasma.

The silicon dot forming method using the silicon sputter target formed of the silicon film may be called “first method” or “first silicon dot forming method”.

In the first method, a silicon film which becomes a silicon sputter target on the inner wall of the vacuum chamber is formed, so that a silicon sputter target of larger area can be easily obtained than when commercially available silicon sputter target is provided at an independent step, whereby silicon dots can be easily formed over a wider area of the substrate.

The term “inner wall of the vacuum chamber” used herein may be an inside of the chamber wall forming the vacuum chamber or may be an inner wall formed inside the chamber wall, or may be a combination thereof.

The inner wall of the vacuum chamber may be made of, for example, a conductive material or semi-conductive material, and a bias voltage may be applied to the silicon sputter target formed of the silicon film through the inner wall of the vacuum chamber for control of chemical sputtering.

At least one of the silicon sputter target(s) may be a silicon sputter target provided in the silicon dot forming vacuum chamber.

For example, a target substrate is disposed in a vacuum chamber for forming a silicon sputter target which is communicated with the silicon dot forming vacuum chamber in an airtight fashion with respect to an ambient air.

A silane-containing gas and a hydrogen gas are supplied into the silicon sputter target forming vacuum chamber while a high-frequency power is applied to the gases to generate plasma. A silicon film is formed on the target substrate by the plasma, giving a silicon sputter target, which can be supplied from the silicon sputter target forming vacuum chamber into the silicon dot forming vacuum chamber without exposure to an ambient air and accommodated therein.

The silicon dot forming method by the silicon sputter target prepared in the silicon sputter target forming chamber may be called a second method or a second silicon dot forming method.

When such silicon sputter target is employed, for example, the target substrate is formed of a conductive material or semi-conductive material. A bias voltage is applicable to the sputter target via the target substrate for control of chemical sputtering on the silicon sputter target.

The silicon sputter target may be a silicon film on the inner wall of the vacuum chamber, or may be the silicon film on the target substrate described above.

In such case, the silicon sputter target is kept from exposure to the ambient air so that mixing of an unintended material into the silicon dots can be suppressed and crystalline silicon dots can be formed with substantially uniform particle diameters and substantially uniform density distribution at a low temperature (e.g., at 500 deg. C. or lower).

The silicon sputter target may be a silicon sputter target provided in the vacuum chamber in a prepared form at an independent step (e.g., commercially available silicon sputter target) as described above.
In other word, at least one of the silicon sputter target(s) may be a silicon sputter target provided in the vacuum chamber in a prepared form at an independent step (e.g., commercially available silicon sputter target).

The silicon dot forming method using such silicon sputter target may be called hereinafter a third method or may be termed a third silicon dot forming method.

The silicon sputter target to be used in the prepared form may be primarily made of silicon, for example, a single-crystalline silicon, a polycrystalline silicon, a microcrystalline silicon, an amorphous silicon or a combination of two or more of them.

The silicon sputter targets to be used are properly selected according to the purpose and include those free of impurities, those containing a very small amount of impurities, those containing an appropriate amount of impurities exhibiting a predetermined resistivity.
For example, the silicon sputter target not containing impurities and the silicon sputter target containing a very small amount of impurities may be a silicon sputter target in which an amount of each of phosphorus (P), boron (B) and germanium (Ge) is lower than 10 ppm.

For example, the silicon sputter targets exhibiting a predetermined resistivity may be those exhibiting the resistivity from 0.001 ohm·cm to 50 ohm·cm.

The sputtering gas may be typically formed of a hydrogen gas. For example, it may also be formed of a mixture of the hydrogen gas and a rare-gas (at least one kind of gas selected from a group including helium gas (He), neon gas (Ne), argon gas (Ar), krypton gas (Kr) and xenon gas (Xe)).

In any one of the silicon dot forming methods described above, the silicon dot forming step is executed in a manner such that a hydrogen gas is supplied as a sputtering gas into the vacuum chamber accommodating the silicon dot formation target substrate, and the high-frequency power is applied to the hydrogen gas to form plasma in the vacuum chamber by which chemical sputtering is effected on the silicon sputter target so that silicon dots can be formed on the silicon dot formation target substrate.

Particularly then, silicon dots of particle diameters not exceeding 20 nm or 10 nm can be directly formed on the substrate at a temperature not exceeding 500 deg. C. (in other words, a low substrate temperature of 500 deg. C. or lower).

When a hydrogen gas is used as the sputtering gas, and the high-frequency power is applied to the hydrogen gas to generate plasma for chemical sputtering of the silicon sputter target, the plasma for chemical sputtering exhibits preferably an electron density of 10¹⁰ pcs(pieces)/cm³ or more.

If the plasma shows an electron density of lower than 10¹⁰ pcs/cm³, the silicon dots may have a lower crystallinity and may be formed at a lower deposition rate.

However, when the electron density is too high, the silicon dots thus formed become damaged or the substrate becomes damaged. In view of this, the upper limit of the electron density is substantially 10¹² pcs/cm³.

Such electron density can be adjusted by controlling at least one of magnitude of high-frequency power to be applied to the hydrogen gas for sputtering, frequency of the power, silicon dot deposition pressure in the vacuum chamber, and the like. The electron density can be, e.g., confirmed by the Langmuir probe method.

In chemical sputtering by the plasma for sputtering of silicon sputter target, the bias voltage for control of the chemical sputtering applied to the silicon sputter target may be in the range of −20 V to +20 V.

If the bias voltage exceeds +20 V, the sputtering by the charged particles (hydrogen ions in the case of hydrogen gas plasma) in the plasma will become ineffective.

If the bias voltage goes beyond +20 V, it results in excess of plasma potential, the electrons in the plasma abruptly flow into the bias applied electrode or a portion corresponding to the bias applied electrode, so that discharge is likely to occur, whereas if a bias voltage is below −20 V, the charged particle energy becomes too high to control the sputtered particle diameters. Depending on the condition, the charged particles flow into the target, making it difficult to do sputtering.

In sputtering, the bias voltage for control of the sputtering is preferably in the range of +20 V to −20 V as described above.

In the silicon dot forming methods described above, the plasma is formed from the silane-containing gas and the hydrogen gas for forming the silicon film serving as the silicon sputter target, and the plasma is formed from the sputtering gas ,e.g., hydrogen gas for sputtering the silicon film.

In each of these kinds of plasma formation, it is preferable that the plasma exhibits a ratio (Si(288 nm)/Hβ) of 10.0 or lower, and more preferably 3.0 or lower between an emission intensity Si(288 nm) of silicon atoms at a wavelength of 288 nm in the plasma emission and an emission intensity Hβ of hydrogen atoms at a wavelength of 484 nm in the plasma emission. The plasma may exhibit the ratio of 0.5 or lower.

In the silicon forming method, when the emission intensity ratio (Si(288 nm)/Hβ) is 10.0 or lower in the plasma, this represents that the plasma is rich in hydrogen atom radicals.

In the first method, the plasma is formed from the silane-containing gas and the hydrogen gas for forming the silicon film serving as the silicon sputter target on the inner wall of the vacuum chamber and the plasma is formed from, in the second method, the silane-containing gas and the hydrogen gas for forming the silicon film on the sputter target substrate.

In each of these kinds of plasma formation, when the plasma exhibits the emission intensity ratio (Si(288 nm)/Hβ) of 10.0 or lower, and more preferably 3.0 or lower, or 0.5 or lower, a silicon film (silicon sputter target) of good quality suitable for forming the silicon dots on the silicon dot formation target substrate is smoothly formed on the inner wall of the vacuum chamber or the sputter target substrate at a low temperature of 500 deg. C. or lower.

In any one of the silicon dot forming methods, when the plasma used for sputtering the silicon sputter target exhibits the emission intensity ratio (Si(288 nm)/Hβ) of 10.0 or lower, and more preferably 3.0 or lower, or 0.5 or lower, it is possible to form the crystalline silicon dots having substantially uniform particle diameters in a range not exceeding 20 nm (and further 10 nm) and exhibiting a substantially uniform density distribution on the substrate at a low temperature of 500 deg. C. or lower (a substrate temperature of 500 deg. C. or lower).

In any method, when the plasma exhibits the emission intensity ratio of higher than 10.0, the growth of crystal particle (dots) becomes difficult, and amorphous silicon is formed in a larger quantity on the substrate.

Therefore it is proper that the emission intensity ratio is lower than 10.0. To form silicon dots of smaller particle diameters, the emission intensity ratio is more preferably 3.0 or lower, or 0.5 or lower.

When the emission intensity ratio takes an excessively small value, the growth of the crystal particles (dots) becomes slow, and it takes a long time to attain the required dot particle diameter.

If the ration takes a further small value, an etching effect exceeds the dot growth so that the crystal particles can not grow. The emission intensity ratio (Si(288 nm)/Hβ) may be substantially 0.1 or more although the value may be affected by various conditions and the like.

The value of emission intensity ratio (Si(288 nm)/Hβ) can be obtained, for example, based on a measurement result obtained by measuring the emission spectrums of various radicals with an optical emission spectroscopic analyzer for plasma.

The control of emission intensity ratio (Si(288 nm)/Hβ) can be performed by controlling the high-frequency power (e.g., frequency or magnitude of power) applied to the supplied gas(es), vacuum chamber gas pressure during silicon dot formation, and/or an amount of the gas (e.g., hydrogen gas, or hydrogen gas and silane-containing gas) supplied into the vacuum chamber.

In any one of the foregoing silicon dot forming methods, when using the hydrogen gas as the sputtering gas, the chemical sputtering can be effected on the silicon sputter target with the plasma exhibiting the emission intensity ratio (Si(288 nm)/Hβ) of 10.0 or lower, preferably 3.0 or lower, or 0.5 or lower. This promotes formation of crystal nucleuses on the substrate, and the silicon dots grow from the nucleuses.

In this way, since formation of the crystal nucleuses is promoted and silicon dots are made to grow, the nucleuses for growing the silicon dots can be formed relatively readily at a high density even when dangling bonds or steps that can form the nucleuses are not present on the silicon dot formation target substrate.

In a portion where the hydrogen radicals and hydrogen ions are richer than the silicon radicals and silicon ions, and the nucleuses are contained at an excessively large density, desorption of silicon is promoted by a chemical reaction between the excited hydrogen atoms or hydrogen molecules and the silicon atoms, and thereby the nucleus density of the silicon dots on the substrate becomes high and uniform.

The silicon atoms and silicon radicals obtained by decomposition with the plasma and excited by the plasma are absorbed to the nucleuses and grow to the silicon dots by chemical reaction.

During this growth, the chemical reaction of absorption and desorption is promoted owing to the fact that the hydrogen radicals are rich, and the nucleuses grow to the silicon dots having substantially uniform crystal orientations and substantially uniform particle diameters.

Owing to the above, the silicon dots having substantially uniform crystal orientations and particle sizes are formed on the substrate at a high density to exhibit a uniform distribution.

In the silicon dot forming method described above, it is intended to form the silicon dots of minute particle diameters, e.g., of 20 nm(nanometers) or lower, and preferably 10 nm or lower on the silicon dot formation target substrate.

In practice, it is difficult to form silicon dots having extremely small particle diameters, and therefore the particle diameters are about 1 nm(nanometer) or more although this value is not restrictive. For example, the diameters may be substantially in a range of 3 nm -15 nm, and more preferably in a range from 3 nm to 10 nm.

In the silicon dot forming method described above, the silicon dots can be formed on the substrate at a low temperature of 500 deg. C. or lower (i.e., with the substrate temperature of 500 deg. C. or lower) and, in certain conditions, at a low temperature of 400 deg. C. or lower (i.e., with the substrate temperature of 400 deg. C. or lower).

This increases a selection range of the substrate material. For example, the silicon dots can be formed on an inexpensive glass substrate having a low melting point and a heat-resistant temperature of 500 deg. C. or lower.

The silicon dots can be formed at a low temperature as described above.

However, if the temperature of the silicon dot formation target substrate is too low, crystallization of the silicon becomes difficult. Therefore, it is desired to form the silicon dots at a temperature of about 150 deg. C. or higher, or 200 deg. C. or higher (i.e., with the substrate temperature of about 150 deg. C. or higher, or 200 deg. C. or higher), although this depends on other various conditions.

In any one of the silicon dot forming methods, the pressure in the vacuum chamber during the plasma formation may be in a range from about 0.1 Pa to about 10.0 Pa.

If the pressure is lower than 0.1 Pa, the crystal particles (dots) grow slowly, and a long time is required for achieving a required dot particle diameter. If the pressure is smaller than the above, the crystal particles (dots) can not grow.

If the pressure is higher than 10.0 Pa, it becomes difficult to grow the crystal particles (dots), and a large amount of amorphous silicon is formed on the substrate.

When a silicon sputter target is disposed in the silicon dot forming vacuum chamber at an independent step as in the second silicon dot forming method and the third silicon dot forming method using a silicon sputter target in a prepared form, e.g., a commercially available silicon sputter target, the arrangement of the target in the vacuum chamber is merely required to locate the target in the position allowing the chemical sputtering with the plasma.

For example, the target may be arranged, e.g., along the whole or part of the internal wall surface of the chamber, or may be arranged independently in the chamber. It is possible to combine the arrangement along the internal wall surface of the chamber with the independent arrangement.

In the case where the silicon film is formed on the inner wall of the vacuum chamber to provide the silicon sputter target, or the silicon sputter target is arranged along the inner wall surface of the vacuum chamber, the vacuum chamber can be heated to heat the silicon sputter target, and the heated target can be sputtered more readily than the sputter target at a room temperature, and thus can readily form the silicon dots at a high density.

For example, the vacuum chamber may be heated to 80 deg. C. or higher, e.g., by a band heater, heating jacket or the like. In view of economical reason or the like, the upper limit of the heating temperature may be e.g., about 300 deg. C. or lower.

If O-rings or the like are used in the chamber, the temperature must be lower than 300 deg. C. in some cases depending on heat resistance thereof.

In any of the silicon dot forming methods, the high-frequency power is applied to the gas(es) supplied into the vacuum chamber by using electrode which may be of either an inductive coupling type or a capacitive coupling type.

When the employed electrode is of the inductive coupling type to generate inductively coupled plasma, it may be arranged in the vacuum chamber or outside the vacuum chamber. When the electrode of the inductive coupling type (high frequency antenna) is employed, higher high-density, more uniform plasma is more easily obtained as compared with use of the electrode of the cpapacitive coupling type.

The inductive coupling-type antenna disposed in the vacuum chamber can achieve a higher efficiency in utilyzing a high-frequency power than when disposed outside the chamber.

The electrode arranged in the vacuum chamber may be coated with an electrically insulating film containing, e.g., silicon or aluminum (e.g., silicon film, silicon nitride film, silicon oxide film or alumina film) for maintaining high-density plasma, suppressing mixing of impurities into the silicon dots due to sputtering of the electrode surface and the like.

When the electrode is of the capacitive coupling type, it is recommended to arrange the electrode perpendicularly to the substrate surface (more specifically, perpendicularly to a surface including the silicon dot formation target surface) so that it may not impede the silicon dot formation on the substrate.

In any one of the above cases, the frequency of the high-frequency power for the plasma formation may be in a range from about 13 MHz to about 100 MHz in view of inexpensive processing. If the frequency is higher than 100 MHz, the electric power cost becomes high, and matching becomes difficult when the high-frequency power is applied.

In any one of the above cases, a power density (applied power (W: watt))/(vacuum chamber capacity (L: liter)) is preferably in a range from about 5 W/L to about 100 W/L. If it is lower than 5 W/L, such a situation occurs to a higher extent that the silicon on the substrate becomes amorphous silicon, and does not easily form crystalline dots.

If the density is larger than 100 W/L, a large damage is caused to the silicon dot formation target substrate surface (e.g., a silicon oxide film formed over the substrate). The upper limit may be about 50 W/L.

Description was given hereinbefore on silicon dot forming methods. The following first to third silicon dot forming apparatuses can be mentioned as preferred embodiments of the invention.

(1) First Silicon Dot Forming Apparatus
A silicon dot forming apparatus including:
a silicon dot forming vacuum chamber having a holder for holding a silicon dot formation target substrate;
a silicon sputter target arranged in the vacuum chamber;
a hydrogen gas supply device supplying a hydrogen gas into the vacuum chamber;
an exhaust device exhausting a gas from the vacuum chamber;
a high-frequency power applying device applying a high-frequency power to the hydrogen gas supplied into the vacuum chamber from the hydrogen gas supply device, and thereby forming plasma for chemical sputtering on the silicon sputter target; and
a bias applying device applying a bias voltage to the silicon sputter target in effecting the chemical sputtering on the silicon sputter target by the plasma for control of the chemical sputtering.

(2) Second Silicon Dot Forming Apparatus
A silicon dot forming apparatus including:
a silicon dot forming vacuum chamber having a holder for holding a silicon dot formation target substrate;
a hydrogen gas supply device supplying a hydrogen gas into the vacuum chamber;
a silane-containing gas supply device supplying a silane-containing gas into the vacuum chamber;
an exhaust device exhausting a gas from the vacuum chamber;
a first high-frequency power applying device applying a high-frequency power to the hydrogen gas supplied into the vacuum chamber from the hydrogen gas supply device and the silane-containing gas supplied into the vacuum chamber from the silane-containing gas supply device, and thereby forming plasma for forming a silicon film on an inner wall of the vacuum chamber;
a second high-frequency power applying device applying a high-frequency power to the hydrogen gas supplied from the hydrogen gas supply device into the vacuum chamber after formation of the silicon film, and thereby forming plasma for effecting chemical sputtering on the silicon film serving as a silicon sputter target; and
a bias applying device applying a bias voltage to the silicon sputter target in effecting chemical sputtering on the silicon sputter target by the plasma produced from the hydrogen gas for control of the chemical sputtering.

This second silicon dot forming apparatus can implement the first silicon dot forming method. The first and second high-frequency power applying devices may partially or entirely share the same structure.

(3) Third Silicon Dot Forming Apparatus
A silicon dot forming apparatus including:
a first vacuum chamber having a holder for holding a target substrate;
a first hydrogen gas supply device supplying a hydrogen gas into the first vacuum chamber;
a silane-containing gas supply device supplying a silane-containing gas into the first vacuum chamber;
a first exhaust device exhausting a gas from the first vacuum chamber;
a first high-frequency power applying device applying a high-frequency power to the hydrogen gas supplied into the first vacuum chamber from the first hydrogen gas supply device and the silane-containing gas supplied into the first vacuum chamber from the silane-containing gas supply device, and thereby forming plasma for forming a silicon film on the target substrate to obtain a silicon sputter target;
a second vacuum chamber for forming silicon dots communicated with the first vacuum chamber in an airtight fashion with respect to an ambient air and having a holder for holding a silicon dot formation target substrate;
a transferring device transferring the silicon sputter target from the first vacuum chamber into the second vacuum chamber without exposing the silicon sputter target to the ambient air;
a second hydrogen gas supply device supplying a hydrogen gas into the second vacuum chamber;
a second exhaust device exhausting a gas from the second vacuum chamber;
a second high-frequency power applying device applying a high-frequency power to the hydrogen gas supplied from the second hydrogen gas supply device into the second vacuum chamber, and thereby forming plasma for effecting chemical sputtering on the silicon sputter target transferred into the second vacuum chamber; and
a bias applying device applying a bias voltage to the silicon sputter target in effecting chemical sputtering on the silicon sputter target by the plasma for chemical sputtering for control of the chemical sputtering.

This third silicon dot forming apparatus can implement the second silicon dot forming method.

The first and second high-frequency power applying devices may partially or entirely share the same structure.
The first and second hydrogen gas supply devices may partially or entirely share the same structure.
The first and second exhaust devices may partially or entirely share the same structure.

The transferring device may be arranged, e.g., in the first or second vacuum chamber. The first and second vacuum chambers may be directly connected together via a gate valve or the like, or may be indirectly connected together via a vacuum chamber which is arranged between them and is provided with the foregoing transferring device.

In any one of the above-mentioned silicon dot forming apparatuses, the high-frequency power applying device for generating plasma for chemical sputtering from the hydrogen gas in the silicon dot forming vacuum chamber may include a high-frequency discharge antenna for forming an inductively coupled plasma.

The hydrogen gas may be of the type having a rare-gas incorporated.

Any one of these silicon dot forming apparatuses may include an optical emission spectroscopic analyzer for plasma, which is intended to obtain a ratio of (Si(288 nm)/Hβ) between an emission intensity Si(288 nm) of silicon atoms at a wavelength of 288 nm and an emission intensity Hβ of hydrogen atoms at a wavelength of 484 nm in plasma emission of the plasma for chemical sputtering in the silicon dot forming vacuum chamber.

In this case, the apparatus may further include a controller comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0, and controlling at least one of (a) a power output of the high-frequency power applying device for forming plasma for chemical sputtering, (b) a supply amount of the hydrogen gas supplied from the hydrogen gas supply device into the vacuum chamber to form the plasma for chemical sputtering and (c) an exhaust amount of the exhaust device exhausting a gas from the vacuum chamber such that the emission intensity ratio (Si(288 nm)/Hβ) of the plasma in the vacuum chamber changes toward the reference emission intensity ratio.

The reference emission intensity ratio may be determined in a range not exceeding 3.0 or 0.5.

Examples of the optical emission spectroscopic analyzer for plasma include those which comprises a first detecting portion detecting the emission intensity Si(288 nm) of silicon atoms at a wavelength of 288 nm in plasma emission, a second detecting portion detecting the emission intensity Hβ of hydrogen atoms at a wavelength of 484 nm in the plasma emission, and an arithmetic portion obtaining the ratio (Si(288 nm)/Hβ) between the emission intensity Si(288 nm) detected by the first detecting portion and the emission intensity Hβ detected by the second detecting portion.

According to the silicon dot apparatuses described above, the silicon dots having substantially uniform particle diameters can be formed directly on the silicon dot formation target substrate at a low temperature (e.g., 500 deg. C.) with a uniform density distribution.

Examples of the silicon dot forming apparatus and silicon dot forming methods by them will be described with reference to the drawings.

<Example of Silicon Dot Forming Apparatus (Apparatus A)>

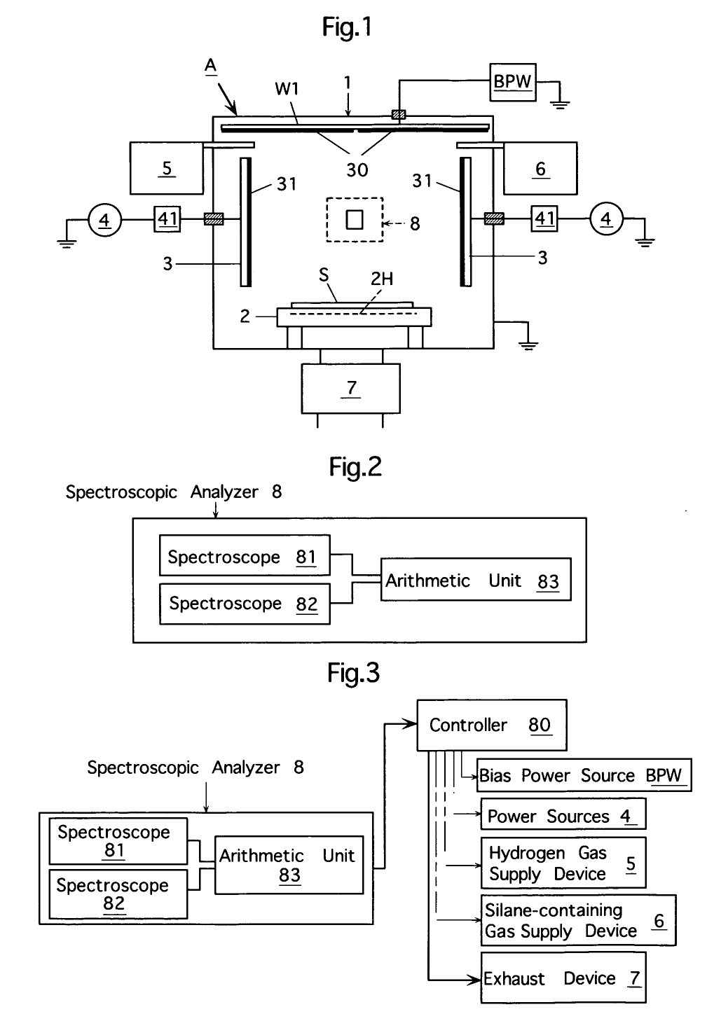

FIG. 1 shows a schematic structure of an example of the silicon dot forming apparatus.
The apparatus A shown in FIG. 1 forms silicon dots on a flat-form silicon dot formation target substrate S.

The apparatus includes a vacuum chamber 1, a substrate holder 2 arranged in the chamber 1, a pair of discharge electrodes 3 laterally spaced from each other in a region above the substrate holder 2 in the chamber 1, high-frequency power sources 4 for discharge each connected to the discharge electrode 3 via a matching box 41, a gas supply device 5 for supplying a hydrogen gas into the chamber 1, a gas supply device 6 for supplying a silane-containing gas containing silicon in the composition (i.e., having silicon atoms) in the chamber 1, an exhaust device 7 connected to the chamber 1 for exhausting a gas from the chamber 1, an optical emission spectroscopic analyzer 8 for plasma for measuring a state of plasma produced in the chamber 1 and the like. The power sources 4, matching boxes 41 and electrodes 3 form a high-frequency power applying device.

The silane-containing gas may be monosilane (SiH₄), and also may be disilane (Si₂H₆), silicon fluoride (SiF₄), silicon tetrachloride (SiCl₄), dichlorosilane (SiH₂Cl₂) or the like.

The substrate holder 2 is provided with a substrate heating heater 2H.

The electrode 3 is provided at its inner side surface with a silicon film 31 functioning as an insulating film. Each electrode 3 is arranged perpendicularly to a surface of the silicon dot formation target substrate S (which will be described later) on the substrate holder 2 (more specifically, perpendicularly to a surface including the surface of the substrate S).

The chamber 1 has an inner wall W1 along a chamber wall (top wall in this example). The inner wall W1 is supported by the chamber wall with an insulating member (not shown). Silicon sputter targets 30 are adhered to the underside of the inner wall W1.

Connected to the inner wall W1 is a DC bias power source BPW for control of chemical sputtering. Therefore a bias voltage can be applied to the silicon sputter targets 30 for control of sputtering on the silicon sputter targets 30.

The silicon sputter target 30 can be selected from among commercially available silicon sputter targets (1)-(3) described below depending on the use or the like of the silicon dots to be formed.

(1) A target made of single-crystalline silicon, a target made of polycrystalline silicon, a target made of microcrystalline silicon, a target made of amorphous silicon or a target made of a combination of two or more of them.

(2) A silicon sputter target which is made of one of the materials in the above item (1), and in which a content of each of phosphorus (P), boron (B) and germanium (Ge) is lower than 10 ppm.

(3) A silicon sputter target made of one of the materials in the above item (1), and exhibiting a predetermined resistivity (e.g., a silicon sputter target exhibiting the resistivity from 0.001 ohm·cm to 50 ohm·cm).

The power source 4 is of an output-variable type, and can supply a high-frequency power at a frequency of 60 MHz. The frequency is not restricted to 60 MHz, may be selected from a range, e.g., from about 13.56 MHz to about 100 MHz, or from a higher range.

The DC power source BPW is also of an output-variable type.
The chamber 1 and the substrate holder 2 are grounded.

The gas supply device 5 includes a hydrogen gas source as well as a valve, a massflow controller for flow control and the like which are not shown in the figure.

The gas supply device 6 can supply a silane-containing gas such as monosilane (SiH₄), and includes a gas source of the monosilane as well as a valve, a massflow controller for flow control and the like which are not shown in the figure.

The exhaust device 7 includes an exhaust pump as well as a conductance valve for controlling an exhaust flow rate and the like which are not shown in the figure.

The optical emission spectroscopic analyzer 8 for plasma can detect the emission spectrums of products of gas decomposition, and the emission intensity ratio (Si(288 nm)/Hβ) can be obtained based on a result of the detection.

A specific example of the optical emission spectroscopic analyzer 8 for plasma may include, as shown in FIG. 2, a spectroscope 81 detecting the emission intensity Si(288 nm) of silicon atoms at a wavelength of 288 nm in plasma emission in the vacuum chamber 1, a spectroscope 82 detecting the emission intensity Hβ of hydrogen atoms at a wavelength of 484 nm in the plasma emission, and an arithmetic unit 83 obtaining the ratio (Si(288 nm)/Hβ) between the emission intensity Si(288 nm) and the emission intensity Hβ detected by the spectroscopes 81 and 82. Instead of the spectroscopes 81 and 82, photosensors each provided with a filter may be employed.

<Silicon Dot Formation by Apparatus A Using Hydrogen Gas As Sputtering Gas for Sputtering Silicon Sputter Target>

Description will now be given on an example of formation of the silicon dots on a substrate S by the silicon dot forming apparatus A described above, and particularly on the case where only the hydrogen gas is used as the plasma formation gas.

When forming the silicon dots, the pressure in the vacuum chamber 1 is kept in a range from 0.1 Pa to 10.0 Pa. The vacuum chamber pressure can be sensed , e.g., by a pressure sensor (not shown) connected to the chamber.

First, prior to the silicon dot formation, the exhaust device 7 starts exhausting from the chamber 1. A conductance valve (not shown) of the exhaust device 7 is already adjusted in view of the above pressure from 0.1 Pa to 10.0 Pa for the silicon dot formation in the chamber 1.

When the exhaust device 7 lowers the pressure in the chamber 1 to a predetermined value or lower, the gas supply device 5 starts supplying the hydrogen gas into the chamber 1, and the power sources 4 apply the power to the electrodes 3 to produce plasma from the supplied hydrogen gas.

The bias power source BPW apply a bias voltage to the silicon sputter targets 30 via the internal wall W1. The bias voltage is adjusted according to the bias voltage of −20 to +20 V at the time of silicon formation.

From the gas plasma thus produced, the optical emission spectroscopic analyzer 8 for plasma calculates the emission intensity ratio (Si(288 nm)/Hβ), and determines the magnitude of the high-frequency power (e.g., in a range from 1000 watts to 8000 watts in view of cost), the amount of supplied hydrogen gas, the pressure in the chamber 1 and the like such that the above calculated ratio may change toward a range from 0.1 to 10.0, and more preferably to a range from 0.1 to 3.0, or from 0.1 to 0.5.

The magnitude of the high-frequency power is determined such that the power density (applied power (W: watt))/(vacuum chamber capacity (L: liter)) of the high-frequency power applied to the electrodes 3 falls within a range from 5 W/L to 100 W/L, or in a range from 5 W/L to 50 W/L.

After determining the silicon dot formation conditions as described above, the silicon dots are formed according to the conditions.

When forming the silicon dots, the silicon dot formation target substrate S is arranged on the substrate holder 2 in the chamber 1, and is heated by the heater 2H to a temperature (e.g., of 400 deg. C.) not exceeding 500 deg. C. The exhaust device 7 operates to maintain the pressure for the silicon dot formation in the chamber 1, and the gas supply device 5 supplies the hydrogen gas into the chamber 1 so that the power sources 4 apply the high-frequency power to the discharge electrodes 3 to produce the plasma from the supplied hydrogen gas.

Further the bias power source BPW applies a bias voltage in the range of −20 V to +20 V to the silicon sputter targets 30 for control of chemical sputtering.

In this way, the ratio (Si(288 nm)/Hβ) between the emission intensity Si(288 nm) of silicon atoms at the wavelength of 288 nm and the emission intensity Hβ of hydrogen atoms at the wavelength of 484 nm in plasma emission falls within the range from 0.1 to 10.0, and more preferably within the range from 0.1 to 3.0, or from 0.1 to 0.5, and thus the plasma having the foregoing reference emission intensity ratio or substantially having the foregoing reference emission intensity ratio is generated. Chemical sputtering (reactive sputtering) is effected with the above plasma on the silicon sputter targets 30.

At this operation, a bias voltage for control of chemical sputtering is applied from bias power source BPW to the silicon sputter targets 30, so that the sputtering of the target is performed properly in respect of inhibition from occurrence of discharge, control of diameters of sputter particles or the like.

Thus, silicon dots having the particle diameters of 20 nm or lower and exhibiting the crystallinity can be formed on the surface of the substrate S.

In the silicon dot forming apparatus A described above, each of the electrodes is of a capacitive coupling type having a flat form, but may be an electrode of an inductive coupling type. The electrode of the inductive coupling type may have various forms such as a rod-like form or a coil-like form. The number of the electrode of the inductive coupling type is not restricted.

In the case of employing an electrode of the inductive coupling type as well as the silicon sputter target, the silicon sputter target may be arranged along the whole of or a part of the inner surface of the chamber wall, may be independently arranged in the chamber or may be arranged in both the manners, in spite of whether the electrode is arranged inside the chamber or outside the chamber.

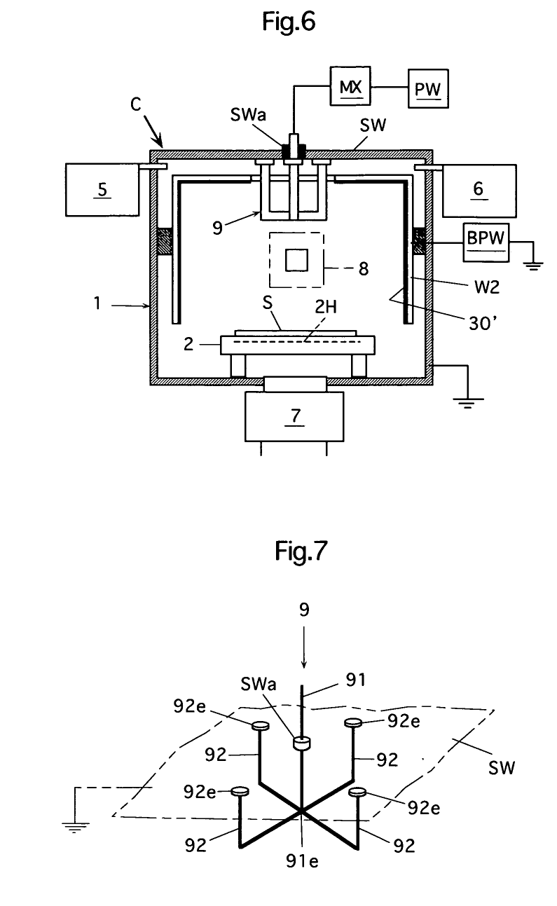

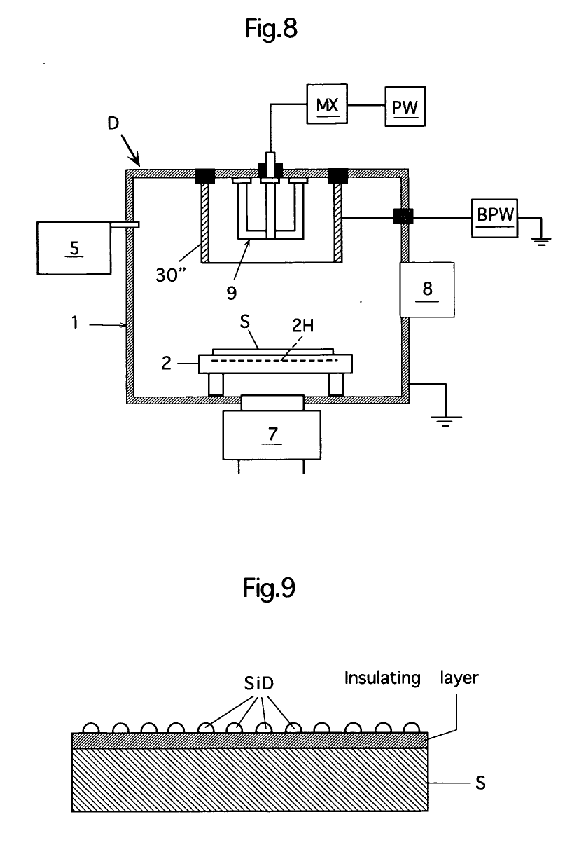

Later, description is made on a silicon dot forming apparatus using inductive coupling type electrode referring to FIGS. 6 and 8 and formation of silicon dots thereby.

In the apparatus A, the chamber 1 may be heated by means (e.g., band heater, heating jacket internally passing heat medium) for heating the vacuum chamber 1 (although not shown in the figure) to heat the silicon sputter target to 80 deg. C. or higher for promoting sputtering of the silicon sputter target.

<Another Example of Silicon Sputter Target>

In forming the silicon dots as described above, the silicon sputter target is formed of a commercially available target, and is arranged in the vacuum chamber 1 in an independent step. However, by employing the silicon sputter target that has not been exposed to an ambient air, it is possible to form the silicon dots that are further protected from unintended mixing of impurities.

More specifically, in the apparatus A described above, the hydrogen gas and the silane-containing gas are supplied into the vacuum chamber 1 by th gas supply devices 5,6 when the substrate S is not yet arranged therein, and the power sources 4 apply the high-frequency power to these gases to form plasma, which forms a silicon film on the inner wall (e.g.,inner wall W1) of the vacuum chamber 1. When forming the silicon film, it is preferable to heat the chamber wall by an external heater.

Thereafter, the substrate S is arranged in the chamber 1, and the chemical sputtering is effected on the sputter target formed of the silicon film with the plasma produced from the hydrogen gas so that the silicon dots are formed on the substrate S as described above.

In the process of forming the silicon film to be used as the silicon sputter target, it is desired for forming the silicon film of good quality that the emission intensity ratio (Si(288 nm)/Hβ) in the plasma falls within the range from 0.1 to 10.0, and more preferably within the range from 0.1 to 3.0, or from 0.1 to 0.5.

<Other Examples of Silicon Dot Forming Method And Apparatus)

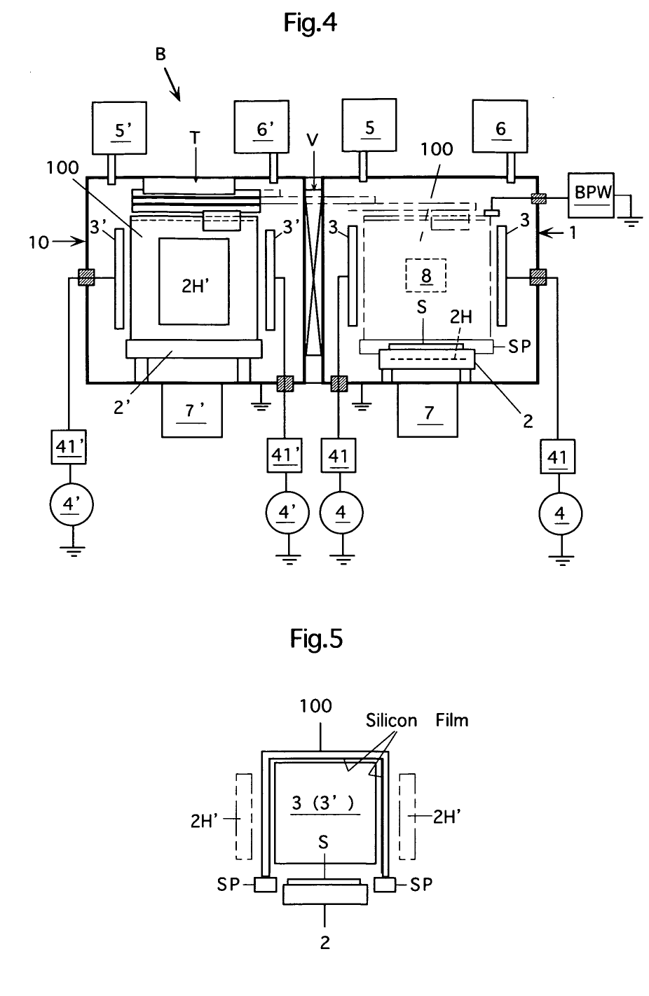

FIG. 4 shows another example of the silicon dot forming apparatus. An apparatus B shown in FIG. 4 is such an apparatus that a vacuum chamber 10 for forming a silicon sputter target is connected to the apparatus A of FIG. 1.

That is, as schematically shown in FIG. 4, the vacuum chamber 10 for forming a silicon sputter target is communicated with the vacuum chamber 1 via a gate valve V in an airtight fashion with respect to an ambient air.

A target substrate 100 is arranged on a holder 2′ in the chamber 10, and an exhaust device 7′ exhausts a gas from the vacuum chamber 10 to keep a predetermined deposition pressure.

A hydrogen gas supply device 5′ and a silane-containing gas supply device 6′ supply the hydrogen gas and the silane-containing gas, respectively into the chamber while keeping the predetermined deposition pressure therein.

Further, an output-variable power sources 4′ apply the high-frequency power to electrodes 3′ in the chamber through matching boxes 41′ to form the hydrogen gas plasma. By this plasma, the silicon film is formed on the target substrate 100 heated by a heater 2H′.

Thereafter, the gate valve V is opened, and a transferring device T transfers the target substrate 100 bearing the silicon film into the vacuum chamber 1, and sets it on a base SP in the chamber 1.

Then, the transferring device T returns, and the gate valve V is airtightly closed. Chemical sputtering is effected on the target by the hydrogen gas plasma while applying a predetermined bias voltage to the target from the bias power source BPW to form the silicon dots on the substrate S arranged in the chamber 1.

FIG. 5 shows positional relationships of the target substrate 100 with respect to the electrodes 3 (or 3′), the heater 2H′ in the chamber 10, the base SP in the chamber 1, the substrate S and the like.

The target substrate 100 has a substantially inverted U-shaped section for obtaining the silicon sputter target of a large area as shown in FIG. 5, although it may have another form. The transferring device T can transfer the substrate 100 without colliding the substrate 100 against the electrodes or the like.

The transferring device T may have various structures provided that it can bring the substrate 100 into the vacuum chamber 1 and can set it therein.

For example, the transferring device T may have a structure having an extensible arm for holding the substrate 100.

When forming the silicon film on the target substrate in the chamber 10, it is desired that the emission intensity ratio (Si(288 nm)/Hβ) of the plasma falls within the range from 0.1 to 10.0, and more preferably within the range from 0.1 to 3.0, or from 0.1 to 0.5.

In connection with the transferring device, a vacuum chamber provided with a transferring device may be arranged between the vacuum chambers 10 and 1, and the chamber provided with the transferring device may be connected to each of the chambers 10 and 1 via a gate valve.

<Another Example of Control of Vacuum Chamber Inner Pressure or the Like>

When forming the silicon dots as described above, manual operations are performed with reference to the emission intensity ratio obtained by the optical emission spectroscopic analyzer 8 for plasma for controlling the output of the output-variable power sources 4, the hydrogen gas supply amount of the hydrogen gas supply device 5 (or the hydrogen gas supply amount of the hydrogen gas supply device 5 and the silane-containing gas supply amount of the silane-containing gas supply device 6), the exhaust amount of the exhaust device 7 and others.

However, the emission intensity ratio (Si(288 nm)/Hβ) obtained by the arithmetic unit 83 of the optical emission spectroscopic analyzer 8 for plasma may be applied to a controller 80 as shown in FIG. 3. The controller 80 may be configured as follows.

The controller 80 determines whether the emission intensity ratio (Si(288 nm)/Hβ) applied from the arithmetic unit 83 is the predetermined reference emission intensity ratio or not.

When it is different from the reference emission intensity ratio, the controller 80 can control at least one of the output of the output-variable power sources 4, the supply amount of the hydrogen gas supplied from the hydrogen gas supply device 5, the supply amount of the silane-containing gas supplied from the silane-containing gas supply device 6 and the exhaust amount of the exhaust device 7.

As a specific example of the controller 80, it may be configured such that the controller 80 controls the exhaust amount of the exhaust device 7 by controlling the conductance valve thereof, and thereby controls the gas pressure in the vacuum chamber 1 to attain the foregoing reference emission intensity ratio.

In this case, the values of the output of the output-variable power sources 4, the hydrogen gas supply amount of the hydrogen gas supply device 5 (or the hydrogen gas supply amount of the hydrogen gas supply device 5 and the silane-containing gas supply amount of the silane-containing gas supply device 6) and the exhaust amount of the exhaust device 7 which can achieve the reference emission intensity ratio or an emission intensity ratio close to it may be employed as initial values of the power output, the hydrogen gas supply amount (or supply amounts of the hydrogen gas and the silane-containing gas) and the exhaust amount. The initial values may be determined in advance by experiments or the like.

When determining the above initial values, the exhaust amount of the exhaust device 7 is determined such that the pressure in the vacuum chamber 1 falls within the range from 0.1 Pa to 10.0 Pa.

The output of the power source 4 is determined such that the power density of the high-frequency power applied to the electrode 3 may fall within the range from 5 W/L to 100 W/L, or from 5 W/L to 50 W/L.

When both the hydrogen gas and silane-containing gas are used as the gases for plasma formation, the gas supply flow rate ratio (silane-containing gas flow rate)/(hydrogen gas flow rate) into the vacuum chamber 1 is determined in a range from 1/200 to 1/30.

For example, the supply flow rate of the silane-containing gas 1 sccm -5 sccm, and (silane-containing gas supply flow rate (sccm)/(vacuum chamber capacity (liter) is determined in a range from 1/200 to 1/30. When the supply amount of silane-containing gas is 1 sccm -5 sccm, the supply amount of hydrogen gas is, for example, in the range of 150 sccm to 200 sccm.

Further, the bias voltage to be applied to the silicon sputter target by the bias power source BPW is determined to be in the range of −20 V to +20 V.

The output of the power source 4 and the hydrogen gas supply amount of the hydrogen gas supply device 5 (or the hydrogen gas supply amount of the hydrogen gas supply device 5 and the silane-containing gas supply amount of the silane-containing gas supply device 6) and the bias voltage will be maintained at the initial values thus determined, and the exhaust amount of the exhaust device 7 is controlled by the controller 80 to attain the reference emission intensity ratio.

<Further Other Examples of Silicon Dot Forming Method And Apparatus>

FIG. 6 shows another example of the silicon dot forming apparatus. The silicon dot forming apparatus C shown in FIG. 6 is an apparatus such that a high-frequency antenna 9 is arranged as suspended from the top wall SW of the vacuum chamber 1 instead of the capacitive coupling type electrodes 3 in the apparatus A of FIG. 1 to produce an inductively coupled plasma, and an internal wall W2 is arranged along the chamber wall of the chamber 1 to which DC bias power source BPW is connected. The internal wall W2 is supported by the chamber wall via an insulating member.

The apparatus C shares substantially the same structure as the apparatus A in other respects. Substantially the same parts and same components as in the apparatus A are indicated by the same reference symbols as in the apparatus A.

The high-frequency discharge antenna 9 extends from the outside of the vacuum chamber 1 into the chamber 1, diverging in an electrically parallel fashion. The termination of diverged part is directly connected to the chamber 1. The chamber 1 is grounded.

Description is given, referring to drawings. As shown in FIG. 7, the high-frequency antenna 9 has a three-dimensional structure, and is formed of a first portion 91, and a plurality of second portions 92.

The first portion 91 extends in a straight rod-like form from the outside of the chamber 1 through its top wall SW. The second portion 92 diverges and extends radially from an inner end 91e of the first portion 91 located in the chamber 1 toward the top wall SW. A termination 92e of each second portion 92 is directly connected to the top wall SW by a connector, and therefore is grounded via the chamber 1.

AS a whole, the group of the second portions 92 has such a form that two antenna portions each having a substantially U-shaped form are combined together to exhibit a crossing form in a plan view and is coupled to the first portion 91.

A surface of a conductive portion of the high-frequency antenna 9 is coated with an insulating film (alumina film in this embodiment).

The first portion 91 of the high-frequency antenna 9 is connected to a high-frequency power source PW via a matching box MX. The matching box MX and the power source PW constitute a high-frequency power applying device.

The first portion 91 has a portion which is located outside the chamber 1 without contributing to plasma production. This portion is extremely short and directly connected to the matching box MX.

The first portion 9 extends through an insulating member SWa which is arranged at the top wall SW of the chamber 1 and serves also as gas-tight sealing.

In this way, the high frequency antenna 9 is so short and has a parallel wiring structure diverging in an electrically parallel fashion in the chamber 1 such that the inductance of the antenna 9 is so reduced.

According to such silicon dot forming apparatus C, silicon dots can be formed in the following manner.

In the beginning, a hydrogen gas and a silane-containing gas are supplied into the vacuum chamber 1 by the gas supply devices 5, 6 without placing a substrate S into the vacuum chamber 1, and a high-frequency power is applied to the gases from the power source PW via the high-frequency antenna 9 to generate plasma.

Then a silicon film 30′ is formed by the plasma on the inner wall W2 in the chamber 1. In forming the silicon film, the chamber wall may be heated by an external heater.

Thereafter the substrate S is placed into the vacuum chamber 1, and chemical sputtering is effected on the silicon film 30′ formed on the inner wall W2 and served as the silicon sputter target by the sputtering plasma formed from the hydrogen gas supplied from the hydrogen gas supply device 5 while applying a bias voltage for control of the sputtering to the target 30′ from the bias source BPW in the same manner as in chemical sputtering of silicon sputter target 30 in the apparatus A, whereby silicon dots are formed on the substrate S.

In forming the silicon film 30′ to be used as the silicon sputter target, it is desired for forming the silicon film of good quality that the emission intensity ratio (Si(288 nm)/Hβ) in the plasma falls within the range from 0.1 to 10.0, and more preferably within the range from 0.1 to 3.0, or from 0.1 to 0.5.

<Further Other Examples of Silicon Dot Forming Method and Apparatus>

FIG. 8 shows another example of the silicon dot forming apparatus. The silicon dot forming apparatus D shown in FIG. 8 is such an apparatus that a silicon sputter target 30″ arranged surrounding the high-frequency antenna 9 is employed instead of the internal wall 2 and the silicon film 30′ formed thereon in the apparatus C of FIG. 6.

The bias power source BPW is connected to the silicon sputter target 30″. The apparatus of FIG. 8 has substantially the same structure in other respects as the apparatus C of FIG. 6.

The silane-containing gas supply 6 is eliminated, since it is not necessary. Substantially the same parts and same components as in the apparatus C are indicated by the same reference symbols as in the apparatus C.

According to the apparatus D, chemical sputtering is effected on the silicon sputter target 30″ by the plasma formed by applying a high-frequency power via antenna 9 to the hydrogen gas supplied into the chamber 1 from the hydrogen gas supply 5 while applying a bias voltage for control of the sputtering to the target 30″ from the bias source BPW in the same manner as in chemical sputtering of silicon sputter target 30 in the apparatus A, whereby silicon dots are formed on the substrate S.

### EXPERIMENTAL EXAMPLE

Description is given on experimental examples of silicon dot formation.

### (1) Experimental Example 1

A silicon dot forming apparatus of the type shown in FIG. 1 was used. However, the silane-containing gas was not employed. The hydrogen gas and the silicon sputter target were used. The silicon dots were directly formed on the substrate.

Dot formation conditions were as follows:
Silicon sputter target: single-crystal silicon sputter target
Substrate: silicon wafer coated with oxide film (SiO₂)
Chamber capacity: 180 liters
High-frequency power source: 60 MHz, 4 kW
Power density: 22 W/L
Substrate temperature: 400 deg. C. (400° C.)
Inner pressure of chamber: 0.6 Pa
Hydrogen supply amount: 100 sccm
Bias voltage: −20 V
Si(288 nm)/Hβ: 0.2

In this way, a substrate S with silicon dots SiD formed thereon as schematically shown in FIG. 9 was obtained.

The section of the substrate S having silicon dots SiD was observed with a transmission electron microscope (TEM), and it was confirmed that the silicon dots having substantially the uniform particle diameters were formed independently from each other.

It was also confirmed that these silicon dots exhibited a uniform distribution and a high density state. From the TEM images, the particle diameters of the silicon dots of 50 in number were measured.

The average of the measured values was 5 nm(nanometers), and it was confirmed that the silicon dots of the particle diameters not exceeding 20 nm and particularly not exceeding 10 nm were formed. The dot density was about 2.0×10¹² pcs(pieces)/cm².

### (2) Experimental Example 2

The silicon dot forming apparatus of the type shown in FIG. 6 was used. First, a silicon film was formed on the internal wall W2 of the vacuum chamber 1 and silicon dots were formed by effecting chemical sputtering on the silicon film served as a sputter target.

Silicon film formation conditions and dot formation conditions were as follows.
Silicon film formation conditions
Internal wall area: About 3 m²
Chamber capacity: 440 liters
High-frequency power source: 13.56 MHz, 10 kW
Power density: 23 W/L
Chamber internal wall temperature: 80 deg. C. (to be heated with a heater disposed inside the chamber)
Inner pressure of chamber: 0.67 Pa
Monsilane supply amount: 100 sccm
Hydrogen supply amount: 150 sccm
Si(288 nm)/Hβ: 2.0

Dot formation conditions Substrate: silicon wafer coated with oxide film (SiO₂)
Chamber capacity: 440 liters
High-frequency power source: 13.56 MHz, 5 kW
Power density: 11 W/L
Internal wall temperature of chamber: 80 deg. C. (to be heated with a heater disposed in the chamber)
Substrate temperature: 430 deg. C.
Inner pressure of chamber: 0.67 Pa
Hydrogen supply amount: 150 sccm (monosilane gas was not used)
Bias voltage: −10 V
Si(288 nm)/Hβ: 1.5

In this way, a substrate S with silicon dots SiD formed thereon as schematically shown in FIG. 9 was obtained.

The section of the substrate S having silicon dots SiD was observed with the transmission electron microscope (TEM), and it was confirmed that the silicon dots were formed independently from each other and the silicon dots exhibited a uniform distribution, a high density state and uniform particle diameters.

Small silicon dots had diameters from 5 nm to 6 nm, and large silicon dots had diameters of 9 nm -11 nm.

From the TEM images, the particle diameters of the silicon dots of 50 in number were measured. The average of the measured values was 8 nm, and it was confirmed that the silicon dots of the particle diameters not exceeding 10 nm were formed. The dot density was about 7.3×10¹¹ pcs/cm².

### (3) Experimental Example 3

A silicon dot forming apparatus of the type shown in FIG. 6 was used. First, a silicon film was formed on the inner wall W2 of the vacuum chamber 1 under the silicon film forming conditions of Experimental Example 2.

Using the silicon film as the sputter target, silicon dots were formed. Dot formation conditions were the same as in Experimental Example 2 excepting for that internal pressure in the chamber was 1.34 Pa and Si(288 nm)/Hβ was 2.5.

In this way, a substrate S with silicon dots SiD formed thereon as schematically shown in FIG. 9 was obtained.

The section of the substrate S having silicon dots SiD was observed with the transmission electron microscope (TEM), and it was confirmed that the silicon dots were formed independently from each other and the silicon dots exhibited a uniform distribution, a high density state and uniform particle diameters.

From the TEM images, the particle diameters of the silicon dots of 50 in number were measured. The average of the measured values was 10 nm, and it was confirmed that the silicon dots of the particle diameters not exceeding 10 nm were formed. The dot density was about 7.0×10¹¹ pcs/cm².

### (4) Experimental Example 4

A silicon dot forming apparatus of the type shown in FIG. 6 was used. First, a silicon film was formed on the inner wall W2 of the vacuum chamber 1 under the silicon film forming conditions in Experimental Example 2, Using the silicon film as the sputter target, silicon dots were formed.

Dot formation conditions were the same as in Experimental Example 2 excepting for that the internal pressure in the chamber was 2.68 Pa and Si(288 nm)/Hβ was 4.6.

In this way, a substrate S with silicon dots SiD formed thereon as schematically shown in FIG. 9 was obtained.

The section of the substrate S having silicon dots SiD was observed with the transmission electron microscope (TEM), and it was confirmed that the silicon dots were formed independently from each other and the silicon dots exhibited a uniform distribution, a high density state and uniform particle diameters.

From the TEM images, the particle diameters of the silicon dots of 50 in number were measured. The average of the measured values was 13 nm, and it was confirmed that the silicon dots of the particle diameters not exceeding 20 nm were formed. The dot density was about 6.5×10¹¹ pcs/cm².

### (5) Experimental Example 5

A silicon dot forming apparatus of the type shown in FIG. 6 was used. First, a silicon film was formed on the inner wall W2 of the vacuum chamber 1 under the silicon film forming conditions in Experimental Example 2.

Using the silicon film as the sputter target, silicon dots were formed. Dot formation conditions were the same as in Experimental Example 2 excepting for that internal pressure in the chamber was 6.70 Pa and Si(288 nm)/Hβ was 8.2.

In this way, a substrate S with silicon dots SiD formed thereon as schematically shown in FIG. 9 was obtained.

The section of the substrate S having silicon dots SiD was observed with the transmission electron microscope (TEM), and it was confirmed that the silicon dots were formed independently from each other and the silicon dots exhibited a uniform distribution and a high density state and had uniform particle diameters.

From the TEM images, the particle diameters of the silicon dots of 50 in number were measured. The average of the measured values was 16 nm, and it was confirmed that the silicon dots of the particle diameters not exceeding 20 nm were formed. The dot density was about 6.1×10¹¹ pcs/cm².

<Another Example of Formation of Substrate Having Silicon Dots>

As seen from the above-described experimental examples, silicon dots Sid can be formed on the surface using a substrate S having an insulating layer such as SiO₂ layer already formed on the surface, whereby silicon dots SiD can be formed on the insulating layer.

Another structure may be available, for example, wherein a chamber for forming an insulating layer as well as a chamber for forming silicon dots may be employed, so that the insulating layer can be formed in the insulating layer forming chamber and wherein a substrate having the insulating layer formed thereon is supplied into the silicon dot forming chamber without exposure to an ambient air and silicon dots are formed on the insulating layer.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A silicon dot forming method including:
a step of arranging a silicon dot formation target substrate in a silicon dot forming vacuum chamber provided with at least one silicon sputter target therein; a silicon dot forming step of forming silicon dots on the silicon dot formation target substrate;
wherein, in the silicon dot forming step, a sputtering gas is supplied into the vacuum chamber; a high-frequency power is applied to the gas to form plasma in the vacuum chamber and a bias voltage for control of chemical sputtering is applied to the silicon sputter target such that the chemical sputtering is effected on the silicon sputter target by the plasma, thereby forming silicon dots on the silicon dot formation target substrate.

2. A silicon dot forming method according to claim 1, wherein at least one of the silicon sputter target(s) is a silicon film formed along an internal wall of the vacuum chamber, the silicon film being formed in a manner such that a silane-containing gas and a hydrogen gas are supplied into the chamber prior to arrangement of the silicon dot formation target substrate into the chamber, and a high-frequency power is applied to the gases to produce plasma in the chamber so that the silicon film is formed along the internal wall of the chamber with the plasma.

3. A silicon dot forming method according to claim 1, wherein at least one of the silicon sputter target(s) is a silicon sputter target arranged in the silicon dot forming vacuum chamber, and wherein the arranged silicon sputter target is a target obtained in a manner such that a target substrate is arranged in a silicon sputter target forming vacuum chamber communicated with the silicon dot forming vacuum chamber in an air tight fashion with respect to an ambient air, a silane-containing gas and a hydrogen gas are supplied into the silicon sputter target forming vacuum chamber, a high-frequency power is applied to the gases to produce plasma in the chamber so that a silicon film is formed on the target substrate to obtain the silicon sputter target, and the silicon sputter target is transferred from the silicon sputter target forming vacuum chamber into the silicon dot forming vacuum chamber without exposing the silicon sputter target to the ambient air.

4. The silicon dot forming method according to claim 1, wherein
at least one of the silicon sputter target(s) is arranged in the silicon dot forming vacuum chamber in a prepared form at an independent step.

5. The silicon dot forming method according to claim 1, wherein
a hydrogen gas is used as the sputtering gas and the high-frequency power is applied to the hydrogen gas to produce the plasma for chemical sputtering.

6. The silicon dot forming method according to claim 5, wherein
the high-frequency power is applied to the sputtering gas using a high-frequency discharge antenna for forming an inductively coupled plasma from the gas.

7. The silicon dot forming method according to claim 5, wherein
the plasma for chemical sputtering exhibits an electron density of 10¹⁰ pcs/cm³ or more.

8. The silicon dot forming method according to claim 5, wherein
said plasma for chemical sputtering exhibits a ratio (Si(288 nm)/Hβ) of 10.0 or lower between an emission intensity Si(288 nm) of silicon atoms at a wavelength of 288 nm and an emission intensity Hβ of hydrogen atoms at a wavelength of 484 nm in plasma emission.

9. A silicon dot forming method according to claim 8, wherein
said emission intensity ratio (Si(288 nm)/Hβ) is 3.0 or lower.

10. A silicon dot forming method according to claim 1, wherein
the bias voltage for control of the chemical sputtering is in a range of −20 V to +20 V.

11. A silicon dot forming apparatus including:
a silicon dot forming vacuum chamber having a holder for holding a silicon dot formation target substrate;
a silicon sputter target arranged in the vacuum chamber;
a hydrogen gas supply device supplying a hydrogen gas into the vacuum chamber;
an exhaust device exhausting a gas from the vacuum chamber;
a high-frequency power applying device applying a high-frequency power to the hydrogen gas supplied into the vacuum chamber from the hydrogen gas supply device, and thereby forming plasma for chemical sputtering on the silicon sputter target; and
a bias applying device applying a bias voltage to the silicon sputter target in effecting the chemical sputtering on the silicon sputter target by the plasma for control of the chemical sputtering.

12. A silicon dot forming apparatus including:
a silicon dot forming vacuum chamber having a holder for holding a silicon dot formation target substrate;
a hydrogen gas supply device supplying a hydrogen gas into the vacuum chamber;
a silane-containing gas supply device supplying a silane-containing gas into the vacuum chamber;
an exhaust device exhausting a gas from the vacuum chamber;
a first high-frequency power applying device applying a high-frequency power to the hydrogen gas supplied into the vacuum chamber from the hydrogen gas supply device and the silane-containing gas supplied into the vacuum chamber from the silane-containing gas supply device, and thereby forming plasma for forming a silicon film on an inner wall of the vacuum chamber;
a second high-frequency power applying device applying a high-frequency power to the hydrogen gas supplied from the hydrogen gas supply device into the vacuum chamber after formation of the silicon film, and thereby forming plasma for effecting chemical sputtering on the silicon film serving as a silicon sputter target; and
a bias applying device applying a bias voltage to the silicon sputter target in effecting chemical sputtering on the silicon sputter target by the plasma produced from the hydrogen gas for control of the chemical sputtering.

13. A silicon dot forming apparatus including:
a first vacuum chamber having a holder for holding a target substrate;
a first hydrogen gas supply device supplying a hydrogen gas into the first vacuum chamber;
a silane-containing gas supply device supplying a silane-containing gas into the first vacuum chamber;
a first exhaust device exhausting a gas from the first vacuum chamber;
a first high-frequency power applying device applying a high-frequency power to the hydrogen gas supplied into the first vacuum chamber from the first hydrogen gas supply device and the silane-containing gas supplied into the first vacuum chamber from the silane-containing gas supply device, and thereby forming plasma for forming a silicon film on the target substrate to obtain a silicon sputter target;
a second vacuum chamber for forming silicon dots communicated with the first vacuum chamber in an airtight fashion with respect to an ambient air and having a holder for holding a silicon dot formation target substrate;
a transferring device transferring the silicon sputter target from the first vacuum chamber into the second vacuum chamber without exposing the silicon sputter target to the ambient air;
a second hydrogen gas supply device supplying a hydrogen gas into the second vacuum chamber;
a second exhaust device exhausting a gas from the second vacuum chamber;
a second high-frequency power applying device applying a high-frequency power to the hydrogen gas supplied from the second hydrogen gas supply device into the second vacuum chamber, and thereby forming plasma for effecting chemical sputtering on the silicon sputter target transferred into the second vacuum chamber; and
a bias applying device applying a bias voltage to the silicon sputter target in effecting chemical sputtering on the silicon sputter target by the plasma for chemical sputtering for control of the chemical sputtering.

14. The silicon dot forming apparatus according to claim 11, 12 or 13, wherein
the high-frequency power applying device for generating the plasma for chemical sputtering from the hydrogen gas in the silicon dot forming vacuum chamber includes a high-frequency discharge antenna for producing an inductively coupled plasma.

15. The silicon dot forming apparatus according to claim 11, 12 or 13, further comprising:
an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in plasma emission of the plasma for chemical sputtering in the silicon dot forming vacuum chamber.

16. The silicon dot forming apparatus according to claim 15, further comprising:
a controller comparing the emission intensity ratio (Si(288 nm)/Hβ) obtained by said optical emission spectroscopic analyzer for plasma with a reference emission intensity ratio (Si(288 nm)/Hβ) predetermined within a range not exceeding 10.0, and controlling at least one of (a) a power output of the high-frequency power applying device for producing the plasma for chemical sputtering, (b) a supply amount of the hydrogen gas supplied from the hydrogen gas supply device into said vacuum chamber to obtain the plasma for chemical sputtering, and (c) an exhaust amount by the exhaust device for exhausting a gas from the vacuum chamber such that the emission intensity ratio (Si(288 nm)/Hβ) of the plasma in the vacuum chamber changes toward the reference emission intensity ratio.
